(19) United States
(12) Patent Application Publication
(10) Pub. No.: US 2002/0061610 A1
(43) Pub. Date: May 23, 2002

(54) Method for fabricating embedded dynamic random access memory

(76) Inventors: Ling-Yuk Tsang, Hsinchu (TW); Sun-Chieh Chien, Hsinchu (TW); Le-Tien Jung, Hsinchu (TW); Der-Yuan Wu, Hsinchu (TW)

Correspondence Address: Daniel R. McClure, THOMAS, KAYDEN, HORSTEMEYER & RISLEY, L.L.P., Suite 1750, 100 Galleria Parkway N.W., Atlanta, GA, 30339, US

(21) Appl. No.: 09/729,547

(22) Filed: Dec. 4, 2000

(30) Foreign Application Priority Data
Nov. 20, 2000 (TW) 89124511

(51) Int. Cl. H01L 21/335

(52) U.S. Cl. 438/142

(57) ABSTRACT

A method of fabricating an embedded dynamic random access memory. After a gate and a source/drain region are formed on a semiconductor substrate, an etch stop layer and a dielectric layer are sequentially formed. The dielectric layer is etched back and patterned, and only the dielectric layer over the source/drain region in the memory circuit region remain. The exposed etch stop layer is removed to expose the salicide layer on the gate and the source/drain region in the logic circuit region.

### CROSS-REFERENCE TO RELATED APPLICATION

This application claims the priority benefit of Taiwan application serial no. 89124511, filed. Nov. 20, 2000.

### BACKGROUND OF THE INVENTION

1. Field of the Invention

The present invention relates in general to a method of fabricating an integrated circuit (IC) device. More particularly, this invention relates to a method of fabricating an embedded dynamic random access memory (DRAM).

2. Description of the Related Art

Embedded dynamic random access memory (DRAM) is a kind of integrated circuit device that integrates a memory cell array and a logic circuit in a single chip. As the distance between the memory cell array and the logic circuit is very close, the signal transmission speed is fast, thus a large amount of data can be accessed in a high speed. These kinds of products are generally applied to electronic products that process huge amount of data such as the graph processor.

The embedded DRAM basically includes a metal oxide semiconductor (MOS) and a capacitor, that is, a storage node of a memory cell, coupled to the drain region of the MOS in the memory circuit region. The dimension of the embedded DRAM being currently fabricated is very small. To reduce the gate resistance of the MOS, a silicide layer on top of a polysilicon layer are formed as the gate. This is the so-called polycide gate. Tungsten silicide and titanium silicide are two popular material for forming the silicide layer.

The conventional method for fabricating the polycide gate includes the following steps. A polysilicon layer and a metal silicide layer are formed on a semiconductor substrate. The polysilicon layer and the metal silicide layer are patterned to form the polycide gate. During the very advanced dual gate logic fabrication process, if tungsten silicide is used for forming the metal silicide layer, a mutual diffusion between the n-type and p-type dopant within the gate is caused due to the very high coefficient of diffusion of the dopant contained in the tungsten silicide. However, the titanium silicide is not compatible for most of the current logic fabrication process.

Another method of reducing the gate resistance of an embedded DRAM, is to perform the salicidation process after the gate is formed of polysilicon. That is, the silicon surface of the gate and the source/drain region are reacted with metal to form the salicide with a low resistance. As the salicidation process consumes a portion of the source/drain region, a shallow junction of the source/drain region easily formed and as a result causing the capitor that is coupled to the source/drain region to have a serious current leakage

### SUMMARY OF THE INVENTION

The present invention provides a method of fabricating an embedded dynamic random access memory. A substrate having a memory circuit region and a logic circuit region is provided. A plurality of gates and source/drain regions is formed on both regions. An etch stop layer and a dielectric layer are formed on the substrate. The dielectric layer is etched back and patterned until the etch stop layer on each gate is exposed. A mask layer is formed on the memory circuit region to remove the remaining dielectric layer on the logic circuit region, so that the etch stop layer covering the logic circuit region is all exposed. The mask layer is removed, and the exposed etch stop layer is removed, so that the gates in both regions, and the source/drain regions in the logic circuit region are exposed. A salicide layer is then formed on the gates and the exposed source/drain region in the logic circuit region.

Thus formed, the source/drain regions in the memory circuit region are protected with the patterned dielectric layer, so that the salicide layer is formed on the source/drain regions in the memory circuit region. As a result, it is avoided that the shallow junction of the source/drain region causes a current leakage of the capacitor coupled to the source/drain region.

Both the foregoing general description and the following detailed description are exemplary and explanatory only and are not restrictive of the invention, as claimed.

### BRIEF DESCRIPTION OF THE DRAWINGS

FIG. 1A to FIG. 1G shows a first embodiment of the invention that provides a method of fabricating an embedded random access memory; and

FIG. 2A to FIG. 2C shows a modification of the method provided in FIGS 1A to 1G, wherein FIG. 2A follows the step as shown in FIG. 1B, FIG. 2C follows the step as shown in FIG. 1F.

### DESCRIPTION OF THE PREFERRED EMBODIMENTS

First Embodiment

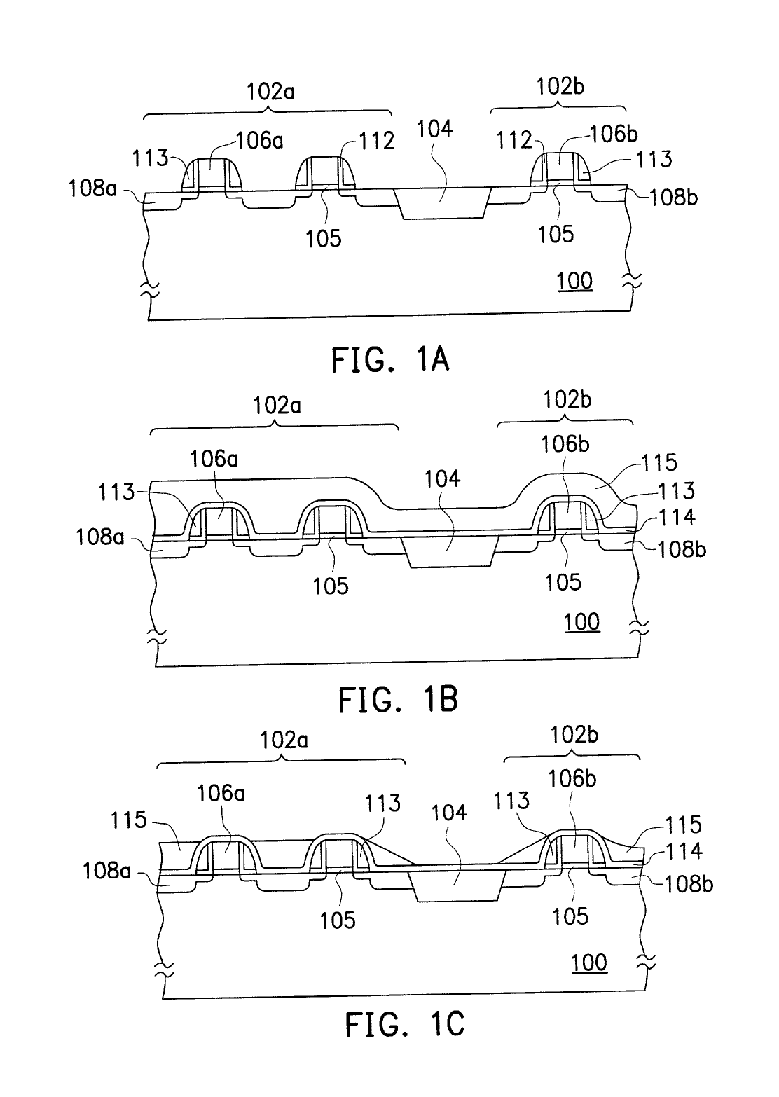

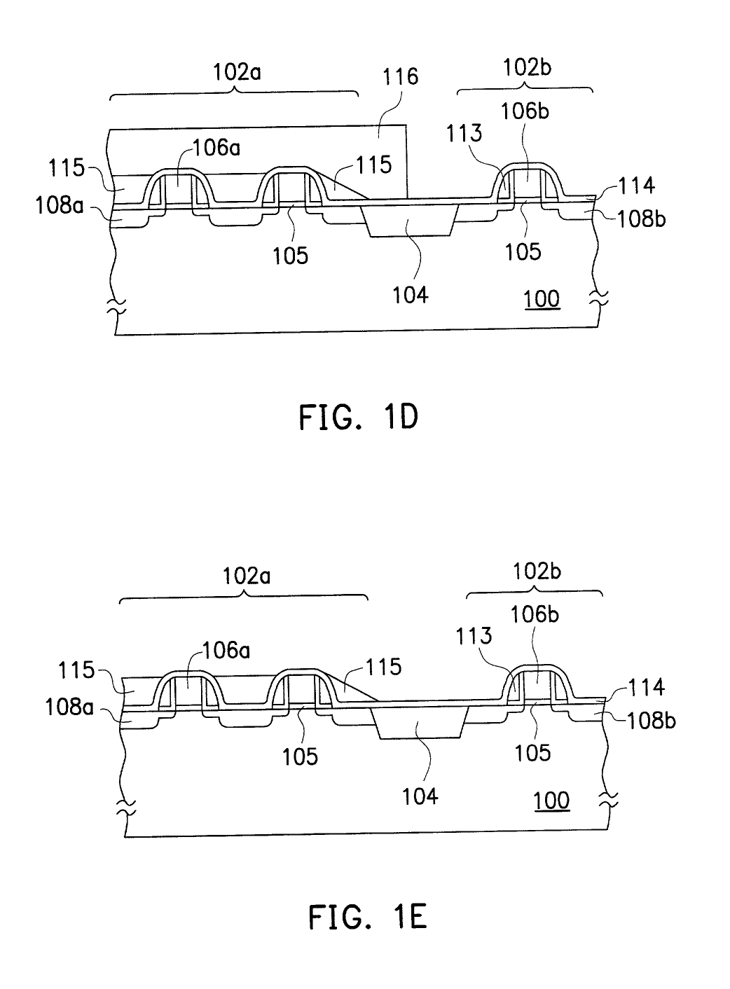

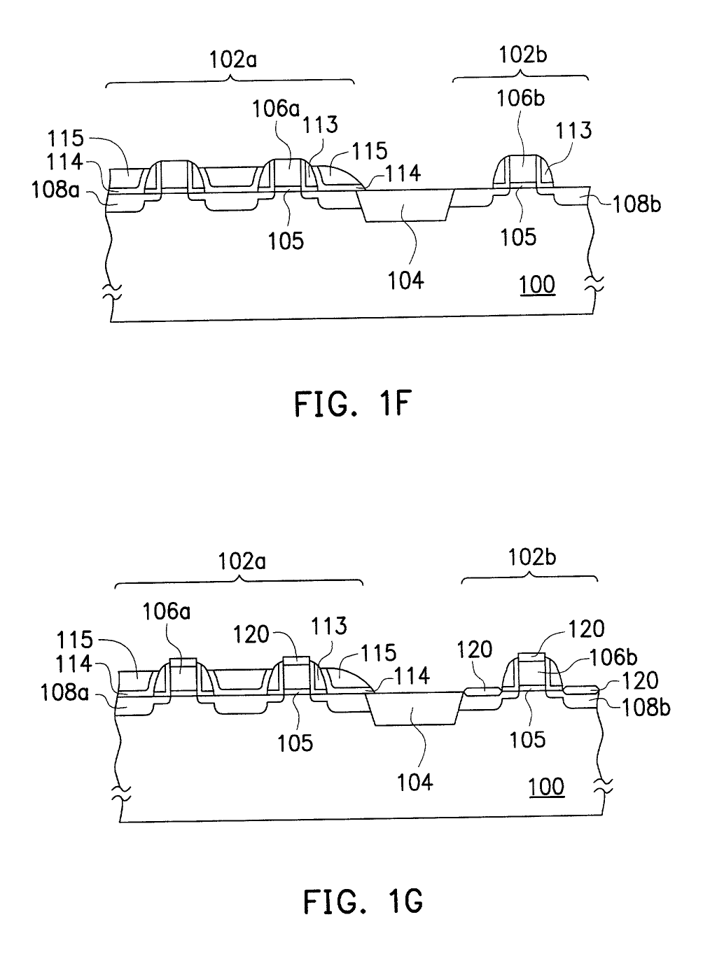

Referring to FIG. 1A, a semiconductor substrate is provided. A shallow trench isolation 104 is formed to differentiate the substrate 104 into a memory circuit region 102a and a logic circuit region 102b of an embedded dynamic random access memory. The memory circuit region 102a and the logic circuit region 102b comprise the gates 106a and 106b, respectively. Under the gates 106a and 106b, a gate oxide layer 105 is formed. On the sidewalls of the gates 106a and 106b, a liner oxide layer 112 is formed. A spacer 113 is formed on the liner oxide layer 112 on the sidewall of each of the gates 106a and 106b. Source/drain regions 108a and 108b are formed in the memory circuit region 102a and the logic circuit region 102b, respectively. In the above structure, the liner oxide layer 112 is thick enough to reduce the stress of the spacer, for example, silicon nitride spacer. Preferably, the liner oxide layer has a thickness of about 200 angstroms.

Referring to FIG. 1B, an etch stop layer 114 is formed on the substrate 100 to cover the gates 106a, 106b and the source/drain regions 108a, 108b. The preferable material for forming the etch stop layer 114 includes silicon nitride, and the thickness of the etch stop layer 114 is about 100 angstroms to about 140 angstroms. A dielectric layer 115, for example, a silicon oxide layer, is formed on the etch stop layer. Preferably, an atmosphere pressure chemical vapor deposition (APCVE) is performed to form a silicon oxide layer with a thickness of about 7000 angstroms to about 9000 angstroms first. Two steps of spin-on glass (SOG) and etch back are further performed to locally planarize the silicon oxide layer. As a result, the dielectric layer 115 in the memory circuit region 102a is planarized.

In FIG. 1C, the dielectric layer 115 is etched back using, for example, wet etching, until the etch stop layer 114 over the gates 106a and 106b are exposed. Meanwhile, the remaining dielectric layer 115 still covers the source/drain regions 108a and 108b.

In FIG. 1D, a mask layer 116, for example, a photoresist layer, is formed to cover the memory circuit region 102a. The dielectric layer 115 in the logic circuit region 102b is exposed and etched away until the etch stop layer 114 covering the source/drain regions 108b is exposed. The step for etching away the dielectric layer 115 includes a wet etching step.

In FIG. 1E, the mask layer 116 is removed, so that the etch stop layer 114 on the gates 106a, 106b and the source/drain region 108b is exposed, while the source/drain region 108a in the memory circuit region 102a is still covered with the remaining dielectric layer 115.

In FIG. 1F, the exposed etch stop layer 114 is removed using, for example, dry etching, so that the gates 106a, 106b and the source/drain region 108b are exposed.

In FIG. 1G, a step of salicidation is performed on the exposed gates 106a, 106b and source/drain region 108b. A metal layer (nummer ?—plus not illustarted) is sputtered on the gates 106a, 106b, the source/drain region 108b and the remaining dielectric layer 115. The metal layer (?) includes a refractory metal such as zirconium (Zr). A rapid thermal process (RTP) is then performed to have the metal layer reacting with the exposed silicon, including the exposed gates 106a, 106b and the source/drain region 108b. As a result, a salicide layer 120 is formed on the gates 106a and 106b, and the source/drain region 108b. The source/drain region 108a is covered and protected by the dielectric layer 115, so that no salicide layer is formed thereon. That is, the source/drain region 108a is not consumed during the salicidation process. There fore there is no concern about forming the shallow junction in the source/drain region 108a in the memory circuit region 102 to cause a current leakage of the capacitor to be formed subsequently. The metal layer is then removed, and a second step of rapid thermal process is performed to adjust the resistance of the salicide layer 120.

Second Embodiment

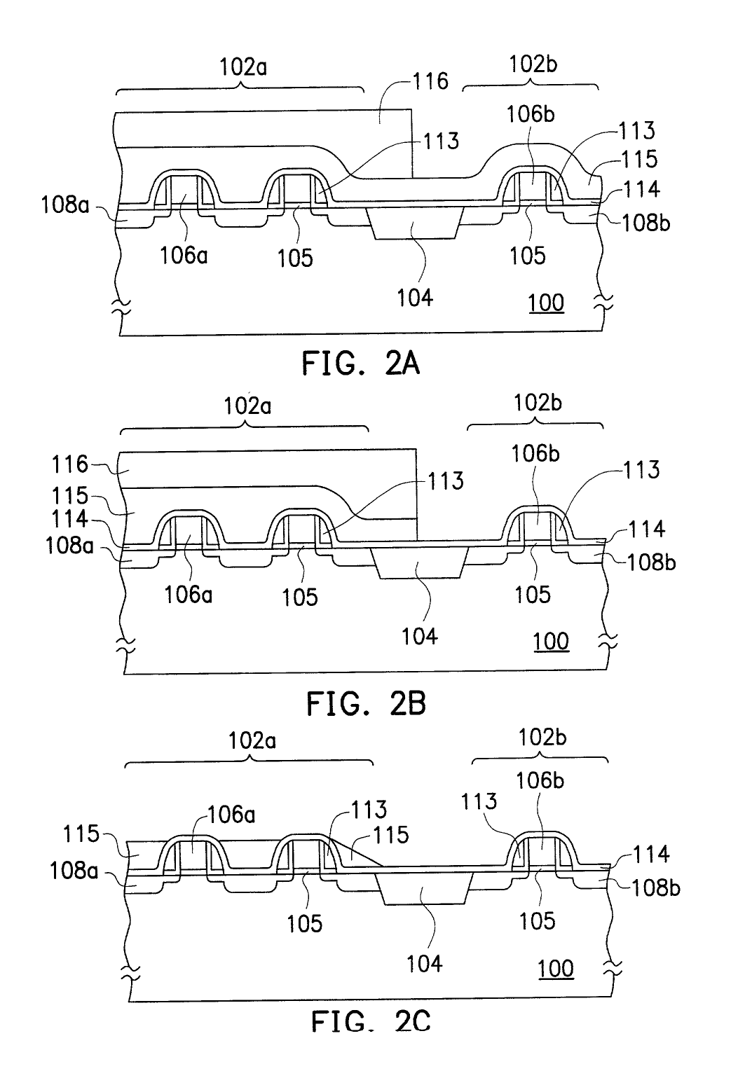

The second embodiment of the invention is illustrated in FIGS. 2A to 2C following FIGS. 1B. That is, the steps as shown in FIGS. 1C to 1E are modified as shown in FIG. 2A to FIG. 2C. Following FIG. 2C, the steps as shown in FIG. 1F and FIG. 1G are then performed.

In FIG. 2A, after the etch stop layer 114 and the dielectric layer 115 are formed as shown in FIG. 1B, a mask layer 116 is formed to cover the memory circuit region 102a before etching back the dielectric layer 115.

In FIG. 2B, the exposed dielectric layer 115 in the logic circuit region 102b is removed to expose the etch stop layer 114. The removal of the dielectric layer 115 in the logic circuit region 102b includes wet etching step.

In FIG. 2C, the mask layer 116 is removed to expose the dielectric layer 115 in the memory circuit region 102a. The dielectric layer 115 is then etched back until the etch stop layer 114 on the gate 106a is exposed. The etch back step includes a wet etching step. As the dielectric layer 115 covering the source/drain region 108a is thicker than that covering the gate 106a, the etch stop layer 114 on the source/drain region 108a is still covered with the dielectric layer 115 when the etch stop layer 114 on the gate 106a is exposed.

As shown in FIG. 1F and 1G, the exposed etch stop layer 114 is removed to expose the gates 106a, 106b and the source/drain region 108b. A salicide layer 120 is then formed on the exposed gates 106a, 106b and the source/drain 108b. The process for forming the salicide layer 120 is similar to that in the first embodiment.

As mentioned above, when the salicide layer 120 is formed on the gates 106a, 106b and the source/drain region 108b in the logic circuit region 102b, the source/drain region 108a in the memory circuit region 102a is still protected and covered with the etch stop layer 114 and the dielectric layer 115. Therefore, the salicide layer 120 is not formed on the source/drain region 102a, that is, the source/drain region 102a in the memory circuit region 102a is not consumed during the salicidation step. Therefore, the leakage current occurring in the conventional method and structure of embedded dynamic random access memory is prevented in this invention.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of fabricating an embedded random dynamic access memory, comprising:
providing a semiconductor substrate comprising a memory circuit region and a logic circuit region;
forming at least a gate and a source/drain region in each of the memory circuit region and logic circuit region;
forming an etch stop layer to cover the gates and the source/drain regions, and a dielectric layer on the etch stop layer;
etching back the dielectric layer until the etch stop layer on the gates in both the memory circuit region and the logic circuit region is exposed, while the etch stop layer covering the source/drain regions is still covered with the remaining dielectric layer;
removing the dielectric layer in the logic circuit layer to expose the etch stop layer covering the source/drain region only in the logic circuit region;
removing the exposed etch stop layer to expose the gates and the source/drain region in the logic circuit region; and
forming a salicide layer on the exposed gates and the exposed source/drain region in the logic circuit region.

2. The method according to claim 1, wherein the step of forming the etch stop layer includes a step of forming a silicon nitride layer.

3. The method according to claim 1, wherein the step of forming the etch stop layer includes a step of forming the etch stop layer with a thickness of about 100 angstroms to about 140 angstroms.

4. The method according to claim 1, wherein the step of forming the dielectric layer includes a process of forming a silicon oxide layer comprising the following steps:
performing an atmosphere pressure chemical vapor deposition to form the silicon oxide layer on the etch stop layer;
forming a first spin-on glass layer on the silicon oxide layer;
performing a first etch back step on the first spin-on glass layer;
forming a second spin-on glass layer on the first spin-on glass layer; and
performing a second etch back step on the second spin-on glass layer.

5. The method according to claim 4, wherein the step of forming the silicon oxide layer includes forming the silicon oxide layer with a thickness of about 7000 angstroms to about 9000 angstroms.

6. The method according to claim 1, wherein the step of forming the salicide layer further comprises:
sputtering a metal layer on the exposed gates, the source/drain region in the logic circuit region and the remaining dielectric layer;
performing a first rapid thermal process step to have the metal layer reacting with the exposed silicon of the exposed gates and the exposed source/drain region, so that the salicide layer is formed;
removing the unreacted metal layer; and
performing a second rapid thermal process to reduce resistance of the salicide layer.

7. The method according to claim 6, wherein the step of forming the metal layer includes a step of forming a zirconium layer.

8. A method of fabricating an embedded dynamic random access memory, comprising:
providing a semiconductor substrate, the semiconductor substrate comprising a memory circuit region and a logic circuit region;
forming a plurality of gates and source/drain regions in the memory circuit region and the logic circuit region;
sequentially forming an etch stop layer and a dielectric layer over the semiconductor substrate;
etching the dielectric layer in the logic circuit region only until the etch stop layer in the logic circuit region is exposed;
removing the dielectric layer on the etch stop layer that covers the gates in the memory circuit region, while the dielectric layer over the source/drain regions in the memory circuit region remains; and
forming a salicide layer on the exposed gates and the exposed source/drain region in the logic circuit region only.

9. The method according to claim 8, wherein the step of forming the etch stop layer includes a step of forming a silicon nitride layer.

10. The method according to claim 8, wherein the step of forming the etch stop layer includes a step of forming the etch stop layer with a thickness of about 100 angstroms to about 140 angstroms.

11. The method according to claim 8, wherein the step of forming the dielectric layer includes a process of forming a silicon oxide layer comprising the following steps:
performing an atmosphere pressure chemical vapor deposition to form the silicon oxide layer on the etch stop layer;
forming a first spin-on glass layer on the silicon oxide layer;
performing a first etch back step on the first spin-on glass layer;
forming a second spin-on glass layer on the first spin-on glass layer; and
performing a second etch back step on the second spin-on glass layer.

12. The method according to claim 11, wherein the step of forming the silicon oxide layer includes forming the silicon oxide layer with a thickness of about 7000 angstroms to about 9000 angstroms.

13. The method according to claim 8, wherein the step of forming the salicide layer further comprises:
sputtering a metal layer on the exposed gates, the source/drain region in the logic circuit region and the remaining dielectric layer;
performing a first rapid thermal process step to have the metal layer reacting with the exposed silicon of the exposed gates and the exposed source/drain region, so that the salicide layer is formed;
removing the unreacted metal layer; and
performing a second rapid thermal process to reduce resistance of the salicide layer.

14. The method according to claim 13, wherein the step of forming the metal layer includes a step of forming a zirconium layer.
